(19) United States
(12) Patent Application Publication
(10) Pub. No.: US 2023/0246137 A1
(43) Pub. Date: Aug. 3, 2023

(54) ULTRAVIOLET LIGHT EMITTING DIODE AND LIGHT EMITTING DEVICE

(71) Applicant: Xiamen San'an Optoelectronics Co., Ltd., Fujian (CN)

(72) Inventors: Yashu ZANG, Fujian (CN); Sihe CHEN, Fujian (CN); Jiali ZHUO, Fujian (CN); Chunlan HE, Fujian (CN); Bin JIANG, Fujian (CN); Chung-Ying CHANG, Fujian (CN); Weichun TSENG, Fujian (CN)

(73) Assignee: Xiamen San'an Optoelectronics Co., Ltd., Fujian (CN)

(21) Appl. No.: 18/086,645

(22) Filed: Dec. 22, 2022

(30) Foreign Application Priority Data
Jan. 28, 2022 (CN) 202210108058.2
Jan. 28, 2022 (CN) 202210108059.7

(51) Int. Cl. H01L 33/38; H01L 33/62; H01L 33/40

(52) U.S. Cl. CPC H01L 33/382; H01L 33/62; H01L 33/405

(57) ABSTRACT

The disclosure provides an ultraviolet light emitting diode including an epitaxial structure, a first contact electrode, a second contact electrode, a first connecting electrode, and a first insulating structure. The epitaxial structure includes a first semiconductor layer, a light emitting layer and a second semiconductor layer stacked in sequence. The first contact electrode is disposed on the epitaxial structure and electrically connected to the first semiconductor layer. The second contact electrode is disposed on the epitaxial structure and electrically connected to the second semiconductor layer. The first connecting electrode is disposed on the first contact electrode. The first insulating structure is disposed on the first connecting electrode and the second contact electrode. The epitaxial structure has multiple conductive holes penetrating from the second semiconductor layer down to the first semiconductor layer.

### CROSS-REFERENCE TO RELATED APPLICATION

This application claims the priority benefit of China application serial no. 202210108058.2, filed on Jan. 28, 2022 and China application serial no, 202210108059.7, filed on Jan. 28, 2022. The entirety of each of the above-mentioned patent application is hereby incorporated by reference herein and made a part of this specification.

### BACKGROUND

### Technical Field

The disclosure relates to the technical field of light emitting diodes, and particularly to an ultraviolet light emitting diode and a light emitting device.

### Description of Related Art

Ultraviolet light emitting diodes (UV LEDs) are solid-state semiconductor devices that can directly convert electrical energy into ultraviolet light. As technology advances, there are prospects for the UV LEDs to be applied to the broad market in the fields of biomedicine, anti-counterfeiting identification, purification (water, air, and the like), computer data storage and military. In recent years, as the demand for drinking water, daily sterilization and disinfection increases, the application of UV LEDs has gradually become a popular research topic. To improve the disinfection efficiency of UV LEDs, most manufacturers go all-out to compete for extracting light from deep UV LEDs as much as possible to realize the maximum light extraction efficiency of deep UV LEDs.

Therefore, how to effectively improve the light extracting effect of an ultraviolet light emitting diode (UV LED) and enhance the disinfection and sterilization performance has become an urgent technical problem to be solved by those skilled in the art.

### SUMMARY

The disclosure provides an ultraviolet light emitting diode including an epitaxial structure, a first contact electrode, a second contact electrode, a first connecting electrode, and a first insulating structure. The epitaxial structure includes a first semiconductor layer, a light emitting layer, and a second semiconductor layer stacked in sequence. The first contact electrode is disposed on the epitaxial structure and electrically connected to the first semiconductor layer. The second contact electrode is disposed on the epitaxial structure and electrically connected to the second semiconductor layer. The first connecting electrode is disposed on the first contact electrode. The first insulating structure is disposed on the first connecting electrode and the second contact electrode. The first insulating structure covers the epitaxial structure, the first connecting electrode and the second contact electrode and has a first opening and the second opening. The first opening is disposed on the first connecting electrode, and the second opening is disposed on the second contact electrode. The epitaxial structure has multiple conductive holes, and the conductive holes penetrate from the second semiconductor layer down to the first semiconductor layer.

The disclosure also provides a light emitting device including the ultraviolet light emitting diode described in any one of the foregoing embodiments.

One advantage of the disclosure is to provide an ultraviolet light emitting diode and a light emitting device. With the matching configuration of the conductive holes, the first connecting electrode and the first insulating structure, the effect of uniform current distribution can be achieved to improve the light emission effect of the ultraviolet light emitting diode. In addition, a relatively large area of the light emitting layer can be retained to increase the light output of the light emitting layer. With the configuration of the first connecting electrode, the first contact electrode thereunder can be protected, and the first contact electrode can be prevented from being corroded by the corrosive solution or gas in the subsequent processes, such as wet etching and dry etching, and the stability and reliability of the ultraviolet light emitting diode can be improved.

Furthermore, an ultraviolet light emitting diode and a light emitting device can also be provided. The matching configuration of multiple conductive holes, two contact electrodes, a first insulating structure, a third connecting electrode, a second insulating structure and an integral structure of two pads contributes to distinguishing the configuration position of the first pad from the configuration position of the second pad. Moreover, no special design is required for the shapes of the first pads and the second pads, and the distance between the first pads and the second pads can also be guaranteed to prevent problems in subsequent installation and use. In addition, by virtue of the configuration of the double insulating layers of the first insulating structure and the second insulating structure, the risk of short circuit caused by the rupture of the insulating structure can also be reduced.

In addition, an ultraviolet light emitting diode and a light emitting device can also be provided. With the configuration of the insulating dimming structure, the light emitting angle can be improved, the reflection of ultraviolet light can be improved, and the light extraction efficiency of the ultraviolet light emitting diode can be improved. The insulating dimming structure can also function as an optical resonance cavity, so that the wave band of the resonance matches the wave band of light emitted by the light emitting layer to further improve the light extraction performance of the ultraviolet light emitting diode. With the configuration of the first protecting electrode, the first contact electrode can be protected from being damaged by factors such as corrosion in the stage of forming the insulating dimming structure. In addition, on the basis of protecting the first contact electrode, the height of the first electrode area can be supplemented, the height difference between the first electrode area and the second electrode area can be reduced, the bonding between the pad electrode and the subsequent packaged substrate can be improved, and meanwhile it has the effect of spreading current and improving electrical properties.

### BRIEF DESCRIPTION OF THE DRAWING

FIG. 1 is a schematic top view of the structure of an ultraviolet light emitting diode according to a first embodiment of the disclosure.

FIG. 2 is a schematic longitudinal cross-sectional view taken along section line A-A of FIG. 1.

FIG. 3 is a schematic structural view of an insulating dimming structure of the disclosure.

FIG. 4 is a schematic view illustrating modulating light of an insulating dimming structure at different thicknesses.

FIG. 5 is a schematic top view of every structure of the ultraviolet light emitting diode shown in FIG. 1.

FIG. 6 is a schematic top view of the structure of an ultraviolet light emitting diode according to a second embodiment of the disclosure.

FIG. 7 is a schematic longitudinal cross-sectional view taken along section line A-A of FIG. 6.

FIG. 8 is a schematic top view of every structure of the ultraviolet light emitting diode shown in FIG. 6.

FIG. 9 is a schematic top view of the structure of an ultraviolet light emitting diode according to a third embodiment of the disclosure.

FIG. 10 is a schematic longitudinal cross-sectional view taken along section line A-A of FIG. 9.

FIG. 11 is a schematic top view of every structure of the ultraviolet light emitting diode shown in FIG. 9.

FIG. 12 is a schematic top view of the structure of the ultraviolet light emitting diode according to the second embodiment of the disclosure.

FIG. 13 is a schematic longitudinal cross-sectional view taken along section line A-A of FIG. 12.

FIG. 14 is a schematic top view of every structure of the ultraviolet light emitting diode shown in FIG. 12.

### DESCRIPTION OF THE EMBODIMENTS

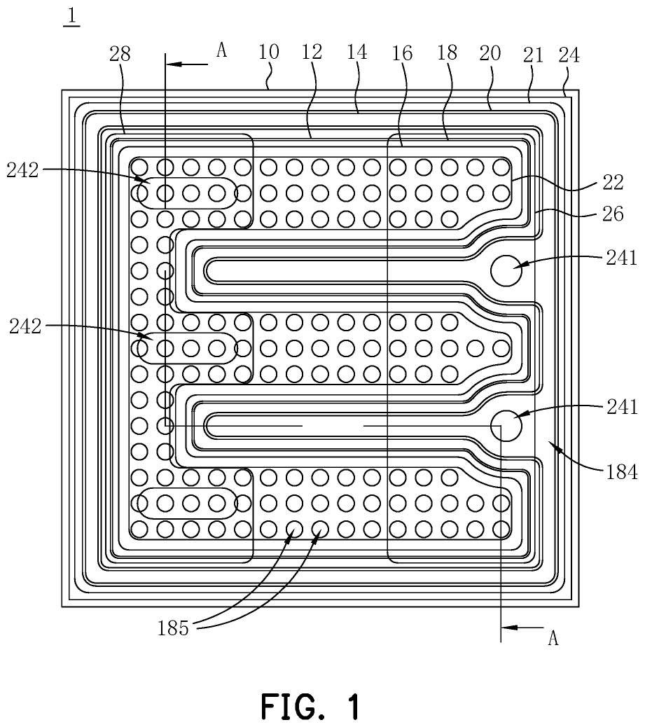

Referring to FIG. 1 to FIG. 5, an embodiment of the disclosure provides an ultraviolet light emitting diode (UV LED) 1.

As shown in the drawings, the UV LED 1 may include at least an epitaxial structure 12, a first contact electrode 14, a second contact electrode 16, an insulating dimming structure 18, a first connecting electrode 21, a second connecting electrode 22, a first insulating structure 24, a first pad 26, and a second pad 28.

Specifically, the UV LED 1 may further include a substrate 10. The substrate 10 may be an insulating substrate, and preferably, the substrate 10 may be made of a transparent material or a translucent material. In the illustrated embodiment, the substrate 10 is a sapphire substrate. In some embodiments, the substrate 10 may be a patterned sapphire substrate, but the disclosure is not limited thereto. The substrate 10 may also be made of a conductive material or a semiconductor material. For example, the material of the substrate 10 may include at least one of silicon carbide (SiC), silicon (Si), magnesium aluminum oxide (MgAl₂O₄), magnesium oxide (MgO), lithium aluminum oxide (LiAlO₂), aluminum gallium oxide (LiGaO₇), and gallium nitride (GaN). To enhance the light extraction efficiency of the substrate 10, especially the effect of light extraction from the substrate surface, the thickness of the substrate 10 may be appropriately increased, and the thickness may be increased to 200-900 μm, such as 250-400 μm, 400-550 μm, or 550-750 μm.

The epitaxial structure 12 is formed on an upper surface of the substrate 10. The epitaxial structure 12 includes a first semiconductor layer 121, a light emitting layer 122, and a second semiconductor layer 123 sequentially stacked along the stacking direction. The stacking direction refers to the direction in which components are stacked on the upper surface of the substrate 10, and the stacking direction in the embodiment is the direction from the substrate 10 to the pads (the first pad 26 and the second pad 28). The epitaxial structure 12 can provide light of a specific center emission wavelength, such as ultraviolet light, deep ultraviolet light, and the like. In the illustrated embodiment, the epitaxial structure 12 providing ultraviolet light is illustrated as an example. Optionally, the epitaxial structure 12 may further include an aluminum nitride underlayer (not shown in the figure) disposed between the upper surface of the substrate 10 and the first semiconductor layer 121, the underlayer is in contact with the upper surface of the substrate 10, and the thickness of the underlayer is preferably 1 μm or less. In other preferred embodiments, a series of hole structures may also he formed in the aluminum nitride underlayer, which facilitates the release of stress in the epitaxial structure 12. The series of holes is preferably a series of elongated holes extending along the thickness of the aluminum nitride, and the depths of the series of elongated holes may be 0.5-1.5 μm, for example.

In the illustrated embodiment, the first semiconductor layer 121 in the epitaxial structure 12 is formed above the substrate 10. The first semiconductor layer 121 may be an N-type semiconductor layer. The light emitting layer 122 may be a quantum well (QW) structure or a multiple quantum well (MQW) structure. The multiple quantum well structure includes multiple quantum well layers and multiple quantum barrier layers disposed alternately in a repeated manner. For example, the multiple quantum well structure may be a multiple quantum well structure of GaN/AlGaN, InAlGaN/InAlGaN or InGaN/AlGaN. In one embodiment, the light emitting wavelength range of the UV LED 1 is 200 nm-420 nm, that is, the light emitting wavelength range of the light emitting layer 122 is 200 nm-420 nm. The second semiconductor layer 123 may be a P-type semiconductor layer, and in some embodiments, the second semiconductor layer 123 includes a P-type doped nitride layer. In a specific implementation aspect, the first semiconductor layer 121 is an n-type AlGaN layer, the light emitting layer 122 is a layer that emits ultraviolet rays and has well layers and barrier layers, the number of repetitions of the well and barrier layers may be between 1 and 10, the well layer may be an AlGaN layer, and the barrier layer may be an AlGaN layer, but the Al composition of the well layer is less than that of the barrier layer. The second semiconductor layer 123 may be a p-AlGaN layer, a p-GaN layer, or a layer structure in which a p-AlGaN layer and a p-GaN layer are stacked in this order. In the embodiment, the second semiconductor layer 123 includes a p-GaN contact layer, and the p-GaN contact layer is connected to the second contact electrode 16 to form a good ohmic contact. The p-GaN contact layer is the upper surface layer of the second semiconductor layer 123, and the thickness of the p-GaN contact layer is 5-50 nm, With the configuration of a thin-film p-GaN contact layer, both the internal quantum light extraction efficiency and the external quantum light extraction efficiency of the UV LED 1 can be taken into account. Specifically, the p-GaN contact layer within this thickness range contributes to the lateral spread of the p-side current without causing excessive light absorption. In addition, the configuration of the epitaxial structure 12 is not limited thereto, and other types of the epitaxial structure 12 may be selected according to actual requirements.

In other embodiments, the first semiconductor layer 121 may also be bonded to the substrate 10 through an adhesive layer.

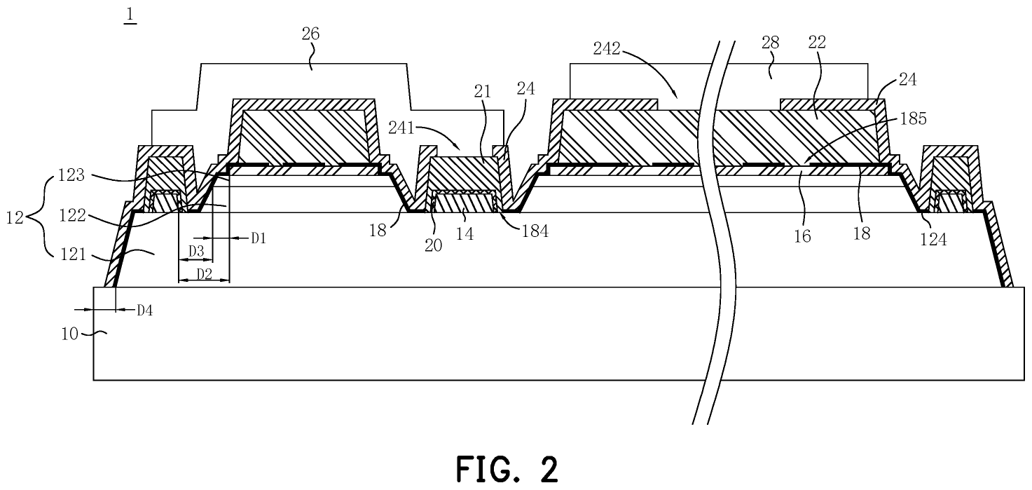

In some embodiments, there is a certain horizontal distance D4 between the edge of the first semiconductor layer 121 and the edge of the substrate 10. As shown in FIG. 2, the sidewall of the first semiconductor layer 121 is disposed inside the sidewall of the substrate 10. In the chip of the UV LED 1, the increase of the thickness of the substrate 10 contributes to improving the light extraction efficiency, but as the thickness of the substrate 10 increases, so does the difficulty in cutting the substrate 10. Therefore, in the embodiment, a certain distance is reserved between the edge of the first semiconductor layer 121 and the edge of the substrate 10, and accordingly the semiconductor layer sequence (e.g., the first semiconductor layer 121) may not be damaged when the substrate 10 is cut, thereby improving the reliability of the UV LED 1. Preferably, the horizontal distance D4 between the edge of the first semiconductor layer 121 and the edge of the substrate 10 is greater than or equal to 2 μm, such as, 4-10 μm.

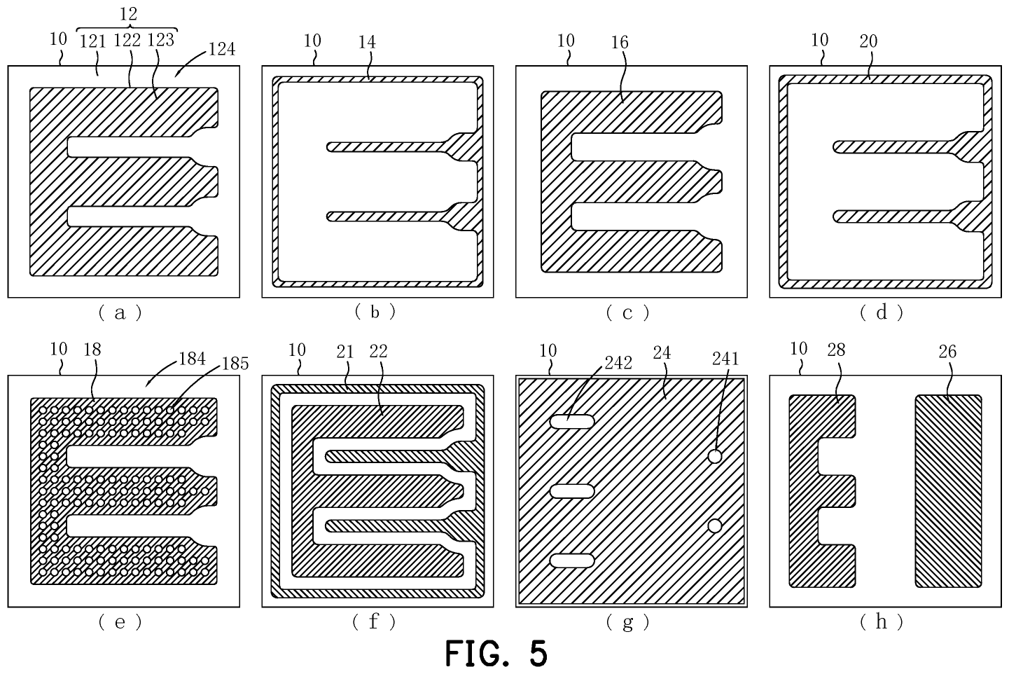

In some embodiments, the second semiconductor layer 123 and the light emitting layer 122 may be removed from part of the epitaxial structure 12 to expose the first semiconductor layer 121 to form one or more mesas 124, that is, the mesa 124 is the surface of the first semiconductor layer 121 that is not covered by the second semiconductor layer 123 and the light emitting layer 122, as shown in part (a) of FIG. 5. In the embodiment, preferably a whole of the mesa 124 is formed, and the mesa 124 is configured to dispose a first contact electrode 54. The distribution of the mesa 124 is not limited to what is shown in part (a) of FIG. 5 and can be designed according to the actual dimension and shape of the chip. The mesas 124 may be connected together or apart from each other. In the UV LED 1, the Al composition of the n-type semiconductor layer (e.g., the first semiconductor layer 121) is usually high, which makes it difficult for currents to spread out, and therefore, currents cannot flow uniformly in the light emitting layer 122 and the p-type semiconductor layer (e.g., the second semiconductor layer 123). Preferably, when viewed from the top of the UV LED 1 toward the epitaxial structure 12, the area of the mesa 124 accounts for 20% to 50% of the area of the epitaxial structure 12 and is relatively uniformly distributed in the epitaxial structure 12. Optionally, the shortest distance from each region of the light emitting layer 122 to the mesa 124 is preferably reserved to be 4-15 μm. Therefore, the current spread of the n-type semiconductor layer (e.g., the first semiconductor layer 121) may be protected, which contributes to improving the internal quantum efficiency of the UV LED 1 and thereby contributes to reducing the forward voltage of the UV LED 1. If the area of the mesa 124 is too large, this may result in a great loss of the area of the light emitting region 122 of the UV LED 1, which is unfavorable for the improvement of the light extraction efficiency of the UV LED 1.

The first contact electrode 14 is electrically connected to the first semiconductor layer 121. Specifically, the first contact electrode 14 is disposed on the upper surface of the first semiconductor layer 121 to form a good ohmic contact with the first semiconductor layer 121, the second contact electrode 16 is disposed on the epitaxial structure 12, and the second contact electrode 16 is disposed on the upper surface of the second semiconductor layer 123 to form a good ohmic contact with the second semiconductor layer 123. The first contact electrode 14 may be a single-layer structure, a double-layer structure, or a multi-layer structure, such as Ti/Al, Ti/Al/Ti/Au, V/Al/Pt/Au, and other stacked structures. In some embodiments, the first contact electrode 14 may be directly formed on the mesa 124 of the epitaxial structure 12. The first semiconductor layer 121 has a relatively high Al composition. The first contact electrode 14 is deposited on the mesa 124, followed by high temperature fusion to form an alloy, thereby forming a good ohmic contact with the first semiconductor layer 121. For example, the first contact electrode 14 may have a Ti/Al/Au alloy structure, a Ti/Al/Ni/Au alloy structure, a Cr/Al/Ti/Au alloy structure, a Ti/Al/Au/Pt alloy structure, or the like.

The second contact electrode 16 is disposed on the second semiconductor layer 123 and may be made of a transparent conductive material or a metal material, which may be suitably selected according to the doping of the surface layer (e.g., the p-GaN contact layer) of the second semiconductor layer 123. In some embodiments, the second contact electrode 16 is made of transparent conductive material. The material may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO), but the embodiments of the disclosure are not limited thereto. Preferably, the light transmittance of the second contact electrode 16 is greater than 40%.

In some embodiments, there is a horizontal distance Dl between the edge of the second contact electrode 16 and the edge of the second semiconductor layer 123, and the horizontal distance D1 is preferably 2-15 μm, such as 5-10 μm. With such a configuration, the risk of leakage (also called reverse leakage current (IR)) and abnormal electrostatic discharge (ESD) taking place in the UV LED 1 may be reduced. Furthermore, the horizontal distance D2 between the end point or edge of the upper surface of the second contact electrode 16 and the edge of the first contact electrode 14 is greater than or equal to 4 μm, preferably greater than or equal to 6 μm. When the distance is too small, leakage is likely to take place. The horizontal distance D2 between the end point or edge of the upper surface of the second contact electrode 16 and the edge of the first contact electrode 14 includes the horizontal distance D3 (greater than or equal to 2 μm) between the edge of the first contact electrode 14 and the edge of the lower surface of the second semiconductor layer 123, and the horizontal distance D1 (greater than or equal to 2 μm) between the edge of the second contact electrode 16 and the edge of the lower surface of the second semiconductor layer 123. With such a configuration, it is ensured that there is a certain distance between the second contact electrode 16 and the mesa 124 on the epitaxial structure 12 to prevent leakage and abnormal ESD of the UV LED 1. Meanwhile, it can he ensured that there is a certain distance between the edge of the first insulating structure 24 and the mesa 124 on the epitaxial structure 12, so that the sidewall of the etched epitaxial structure 12 has a. sufficiently thick first insulating structure 24 to ensure that the UV LED 1 has favorable insulation protection and anti-leakage performance.

The insulating dimming structure 18 covers the epitaxial structure 12 and has a refractive index less than the refractive index of the second contact electrode 16. The insulating dimming structure 18 may be configured to modulate light with a specific wave band emitted by the light emitting layer 122, so that more the light can he extracted, thereby improving the light extraction efficiency of the UV LED 1. Specifically, the insulating dimming structure 18 covers part of the upper surface of the substrate 10, the sidewall and part of the upper surface of the first semiconductor layer 121, the sidewall of the light emitting layer 122, the sidewall and part of the upper surface of the second semiconductor layer 123, and the sidewall and part of the upper surface of the second contact electrode 16. The insulating dimming structure 18 has a first conductive hole 184 and a second conductive hole 185. The first conductive hole 184 is disposed on the first semiconductor layer 121 for exposing the first contact electrode 14, so that the first connecting electrode 21 is electrically connected to the first contact electrode 14 through the first conductive hole 184. The second conductive hole 185 is disposed on the second semiconductor layer 123 for exposing the second contact electrodes 16, so that the second connecting electrode 22 is electrically connected to the second contact electrode 16 through the second conductive hole 185. Preferably, the material of the insulating dimming structure 18 includes a dielectric material with a refractive index less than the refractive index of the second contact electrode 16, and the second contact electrode 16 adopts a transparent conductive material. Moreover, the dielectric material has a low absorption coefficient in the ultraviolet wave band, such as SiO₂ and the like.

With the configuration of the insulating dimming structure 18, the light emitting angle may be improved, the reflection of ultraviolet light may he enhanced, and the light extraction efficiency of the UV LED 1 may be improved. The insulating dimming structure 18 can also function as an optical resonance cavity, so that the wave band of its resonance matches the wave band of light emitted by the light emitting layer 122 to further improve the light extraction performance of the LV LED 1. Two implementations of the insulating dimming structure 18 are illustrated as examples in the subsequent paragraphs, but the disclosure is not limited thereto.

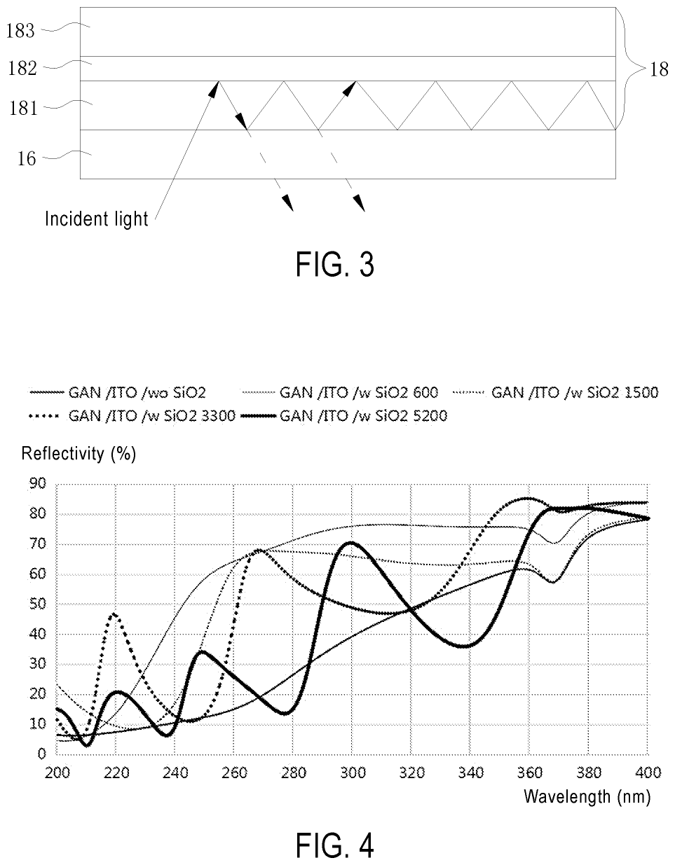

In the first implementation, as shown in FIG. 3 and FIG. 4, the insulating dimming structure 18 includes at least a first insulating layer 181 and a reflecting layer 182 along the stacking direction. The first insulating layer 181 is disposed on the second contact electrode 16, and the reflecting layer 182 is disposed on a surface of the first insulating layer 181 away from the second contact electrode 16, The reflecting layer 182 may be a metal reflecting layer, such as an Al metal reflecting layer, a Rh metal reflecting layer, and the like, and the reflectivity of the reflecting layer 182 is greater than the reflectivity of the second contact electrode 16, preferably 70-100%. The refractive index of the first insulating layer 181 is less than the refractive index of the second contact electrode 16. The light emitted by the light emitting layer 122 penetrates through the second contact electrode 16, is incident into the first insulating layer 181, and may be reflected back and forth in the first insulating layer 181 by the reflecting layer 182 and the second contact electrode 16 on the upper and lower sides, During the incessant reflection of the light, the second contact electrode 16 may incessantly transmit some ultraviolet light toward the direction of the substrate 10 and then to the outside.

The insulating dimming structure 18 may further include a second insulating layer 183, and the reflecting layer 182 is disposed between the first insulating layer 181 and the second insulating layer 183. The first insulating layer 181 and the second insulating layer 183 cover the reflecting layer 182. Through the first insulating layer 181 and the second insulating layer 183, the metal reflecting layer 182 is completely covered by the first insulating layer 181 and the second insulating layer 183 thereby without being involved in conduction, which may prevent the electrical abnormality resulting from the migration of the reflecting layer 182 after power-on. The materials of the first insulating layer 181 and the second insulating layer 183 may include at least one of SiO₂, SiN, SiOₓN_{y}, Si₃N₄, Al₂O₃, TiN, AlN, ZrO₂, TiAlN, TiSiN, HfO₂, TaO₂ and MgF₂ or a combination thereof.

Furthermore, as shown in FIG. 4, the thickness of the first insulating layer 181 is one of the important factors affecting the modulated wavelength light. In FIG. 4, GAN/ITO corresponds to the surface layer of the second semiconductor layer 123 and the second contact electrode 16, respectively. “wo” and “w” refer to a scenario in which the first insulating layer 181 of SiO₂ does not exist and a scenario in which the first insulating layer 181 of SiO₂ exists, respectively. Numbers, such as 600, 1500, and so on, represent the thickness. As shown in FIG. 4, when the first insulating layer 181 of SiO₂ does not exist, the reflectivity for deep ultraviolet light with a wavelength of 260-280 nm is about 15%-27%; when the first insulating layer 181 of SiO₂ exists and its thickness is 600 Å, the reflectivity for deep ultraviolet light with a wavelength of 260-280 nm increases to 65%-75%, and the resonance peak corresponds to a wide range of this wave band; when the first insulating layer 181 of SiO₂ exists and its thickness is 1500 Å, the reflectivity for deep ultraviolet light with a wavelength of 260-280 nm is 62%-68%; when the first insulating layer 181 of SiO₂ exists and its thickness is 3300 Å, the reflectivity of the deep ultraviolet light with a wavelength of 260-280 nm changes sharply, the reflectivity of the deep ultraviolet light with a wavelength of 265-280 nm may reach 50% or more, the reflectivity of the deep ultraviolet light with a wavelength of 260-265 nm may reduce to about 40%, forming a high-order resonance, and the resonance peak corresponds to a relatively narrow range of this wave band; when the first insulating layer 181 of SiO₂ exists and its thickness is 5200 Å, the reflectivity for deep ultraviolet light with a wavelength of 260-280 nm is 13%-28%.

Specifically, the insulating dimming structure 18 may be configured to modulate the light path of the light emitted by the light emitting layer 122, thereby increasing the light output. In modulating the light path, the first insulating layers 181 with different thicknesses have the following differences. When the thickness of the first insulating layer 181 reaches a certain basic value, a resonance cavity may be formed, and the wave band of its resonance matches the wave band of light emitted by the light emitting layer, thereby improving the light extraction performance of the UV LED 1. However, when the thickness exceeds a certain limit, the more the thickness, the more obvious the high-order resonance. Therefore, by limiting the maximum thickness of the first insulating layer 181, the occurrence of high-order resonance (e.g., the curve with a thickness of 5200 Å) resulting from the excessive thickness of the first insulating layer 181 may be prevented. The wavelength of light emitted by the light emitting layer 122 generally distributes within a wavelength range (e.g., 260-280 nm), and when the thickness of the first insulating layer 181 is too large, high-order resonance may be formed between the first insulating layer 181 and the second contact electrode 16. High-order resonance refers to a large difference in the reflection effect of light within a wavelength range, so that the range of the target wave band corresponding to the resonance peak may be relatively narrow. Meanwhile, some wavelengths of light emitted by the light emitting layer 122 may exceed or even shift from the resonance peak, resulting in a decrease in reflectivity. If a low-order resonance (e.g., the curve trend of thickness 600 Å and the curve trend of thickness 1500 Å) is formed, the range of the target band corresponding to the resonance peak is relatively wide, and the light in the band has a higher reflectivity and stronger reflection performance. The reasons for limiting the minimum thickness of the first insulating layer 181 are as follows. The first insulating layer 181 with a certain thickness can better protect the metal reflecting layer 182 thereon, and the electrical abnormality caused by the diffusion or migration of the metal reflecting layer 182 may be prevented.

Preferably, when the refractive index of the dielectric material of the first insulating layer 181 is less than the refractive index of the second contact electrode 16, the thickness of the first insulating layer 181 is 1200-5000 Å, such as 1500 Å, 3000 Å, and the like. In addition, the thickness of the first insulating layer 181 can also be 600 Å, the thicknesses mentioned above may form a favorable low-order resonance cavity, and the overall light extraction performance is favorable.

In the second implementation, the insulating dimming structure 18 may be an insulating layer and requires no high reflection characteristics but functions as an optical resonance cavity with the reflection characteristics of the reflection electrode of the second connecting electrode 22 (i.e., the second connecting electrode 22 includes a reflective metal layer, such as an Al metal layer, a Rh metal layer, and the like) so that the wave band of its resonance matches the wave band of light emitted by the light emitting layer 122, thereby improving the light output performance of the UV LED 1, In other words, the light emitted by the light emitting layer 122 passes through the second contact electrode 16, is incident to the insulating dimming structure 18, and is reflected back and forth in the insulating dimming structure 18 by the second connecting electrode 22 and the second contact electrode 16 on the upper and lower sides. During the incessant reflection of the light, the second contact electrode 16 may incessantly transmit some ultraviolet light toward the direction of the substrate 10 and then to the outside, In this case, the thickness of the insulating light modulating structure 18 is one of the important factors affecting the modulated wavelength light. For the specific illustration of the insulating dimming structure 18 with different thicknesses in modulating the light path, refer to the illustration of FIG. 4 and part of the illustration of the first insulating layer 181. Preferably, the thickness of the insulating dimming structure 18 is 1200-5000 Å, such as 1500 Å, 3000 Å, and the like. Such a thickness may form a favorable low-order resonance cavity, and the overall light extraction performance is favorable.

The first connecting electrode 21 is connected to the first contact electrode 14 through the first conductive hole 184, which has functions in not only current spreading but also protecting the first contact electrode 14 thereunder as well as providing support and raise.

Preferably, the first connecting electrode 21 completely covers the first contact electrode 14 to prevent metal precipitation in the first contact electrode 14, for example, to prevent Al metal from precipitation. The material of the first connecting electrode 21 may be one or more selected from Cr, Pt, Au, Ni, Ti and Al. Preferably, the metal surface layer of the first connecting electrode 21 in contact with the first insulating structure 24 and the insulating dimming structure 18 is a Ti metal layer or a Cr metal layer, so that a stable attachment relationship is formed between the first connecting electrode 21 and the first insulating structure 24 as well as between the first connecting electrode 21 and the insulating dimming structure 18.

The second connecting electrode 22 is connected to the second contact electrode 16 through the second conductive hole 185. The material of the second connecting electrode 22 may be one or more selected from Cr, Pt, Au, Ni, Ti and Al. Preferably, the metal surface layer of the second connecting electrode 22 in contact with the first insulating structure 24 and the insulating dimming structure 18 is a Ti metal layer or a Cr metal layer, so that a stable attachment relationship is formed between the second connecting electrode 22 and the first insulating structure 24 as well as between the second connecting electrode 22 and the insulating dimming structure 18.

The first insulating structure 24 covers the epitaxial structure 12, the insulating dimming structure 18, the first connecting electrode 21, and the second connecting electrode 22. The first insulating structure 24 has a first opening 241 and a second opening 242, the first opening 241 is disposed on the first connecting electrode 21 for exposing the first connecting electrode 21, and the second opening 242 is disposed on the second connecting electrode 22 for exposing the second connecting electrode 22. The first insulating structure 24 has different functions according to the position involved. For example, the sidewall coveting the epitaxial structure 12 is configured to prevent the electrical connection between the first semiconductor layer 121 and the second semiconductor layer 123 resulting from the leakage of the conductive material, thereby reducing the abnormal short circuit of the UV LED 1, but the embodiments of the disclosure are not limited thereto. The material of the first insulating structure 24 includes a non-conductive material. The non-conductive material is preferably an inorganic material or a dielectric material. The inorganic material may contain silica gel. The dielectric material includes electrical insulating materials such as aluminum oxide, silicon nitride, silicon oxide, titanium oxide, or magnesium fluoride. For example, the insulating layer may be silicon dioxide, silicon nitride, titanium oxide, tantalum oxide, niobium oxide, barium titanate, or a combination thereof. The combination thereof may be, for example, a Bragg reflector (DBR) formed by repeatedly stacking two materials.

The first pad 26 is disposed on the first insulating structure 24 and connected to the first connecting electrode 21 through the first opening 241. The second pad 28 is disposed on the first insulating structure 24 and connected to the second connecting electrode 22 through the second opening 242. The first pad 26 and the second pad 28 may be formed simultaneously using the same material in the same process and thus may have the same layer configuration.

Optionally, in one embodiment, to protect the first contact electrode 14 from being damaged by factors such as corrosion in the stage of forming the insulating dimming structure 18, a first protecting electrode 20 is disposed on the first contact electrode 14, and the first protecting electrode 20 is formed on the epitaxial structure 12 before the insulating dimming structure 18. That is, as shown in FIG. 1 and FIG. 2, the UV LED 1 further includes the first protecting electrode 20, and the first protecting electrode 20 completely covers the first contact electrode 14 to protect the first contact electrode 14 and improve the stability and reliability of the UV LED 1. In one embodiment, the first protecting electrode 20 may be a single-layer structure, such as a Ti metal layer structure, to protect the first contact electrode 14, and the thickness of the first protecting electrode 20 may be 10 nm or more, such as probably 30-50 nm. The first protecting electrode 20 may also be a multi-layer structure, such as a variety of structures selected from Cr, Pt, u Ni, Ti, and Al. On the basis of the protecting function, the height of the first electrode area (e.g., the first contact electrode 14 and the first connecting electrode 21) may also be supplemented to reduce the height difference between the first electrode area and the second electrode area (e.g., the second contact electrode 16 and the second connecting electrode 22), thereby improving the bonding between the pad electrodes (the first pad 26 and the second pad 28) and the substrate packed subsequently, and meanwhile it also has the effect of spreading current and improving electrical properties.

As shown in FIG. 5, the UV LED 1 may be formed by the manufacturing method as follow.

First, as shown in part (a) of FIG. 5, the epitaxial structure 12 including the first semiconductor layer 121, the light emitting layer 122, and the second semiconductor layer 123 is grown on the substrate 10. Next, the second semiconductor layer 123 is etched downward until the first semiconductor layer 121 is etched, so that the first semiconductor layer 121 is exposed to serve as the mesa 124 of the electrode. As shown in part (a) of FIG. 5, after etching, the second semiconductor layer 123 is “E-shaped”, and the mesa 124 of the electrode on the first semiconductor layer 121 is completely communicating. Note that the disclosure is not limited to the shape, different shapes may be selected according to requirements, and mesa 124 of the electrode on the first semiconductor layer 121 may not be completely communicating. In addition, the edge portion of the epitaxial structure 12 may be optionally removed to further expose the substrate 10 to facilitate subsequent processes, such as cutting.

Next, as shown in part (b) and part (c) of FIG. 5, the first contact electrode 14 is formed on the first semiconductor layer 121, and the second contact electrode 16 is formed on the second semiconductor layer 123. Preferably, the materials of the first contact electrode 14 and the second contact electrode 16 are different. Optionally, considering that in the conventional manufacturing process of the UV LED 1, the N-side electrode is usually annealed at a high temperature to form an alloy electrode, and then a subsequent process, such as wet etching or dry etching, is directly performed to process structures, such as the insulating layer and the like, the N-side electrode is accordingly easily damaged by etching and corrosion, which destroys the overall performance of the UV LED 1. Therefore, the first contact electrode 14 is formed first, and then the second contact electrode 16 is formed. Preferably, the first contact electrode 14 includes various metals, and a metal alloy is formed after high temperature annealing to form a good ohmic contact with the first semiconductor layer 121.

Next, as shown in part (d) of FIG. 5, before forming the insulating dimming structure 18, the first protecting electrode 20 is formed on the first contact electrode 14 to prevent the first contact electrode 14 from being damaged in subsequent processes. Subsequently, as shown in part (e) of FIG. 5, after the formation of the first protecting electrode 20, the preparation of the insulating dimming structure 18 starts. Preferably, the insulating dimming structure 18 has multiple second conductive holes 185, and the multiple second conductive holes 185 are distributed on the second contact electrode 16 in an array, so that the current can distributively flow into the second contact electrode 16 below through the second conductive holes 185 to achieve the effect of uniform current distribution.

Furthermore, as shown in part (f) of FIG. 5, the first connecting electrode 21 is formed on the first protecting electrode 20, and the second connecting electrode 22 is formed on the insulating dimming structure 18. The first connecting electrode 21 is connected to the first protecting electrode 20 through the first conductive hole 184, and the second connecting electrode 22 is connected to the second contact electrode 16 through the second conductive hole 185. Subsequently, as shown in part (g) of FIG. 5, the first insulating structure 24 covering the first connecting electrode 21, the second connecting electrode 22, and the insulating dimming structure 18 is formed.

Finally, as shown in part (h) of FIG. 5, the first pad 26 and the second pad 28 are formed on the first insulating structure 24. The first pad 26 is connected to the first connecting electrode 21 through the first opening 241, and the second pad 28 is connected to the second connecting electrode 22 through the second opening 242.

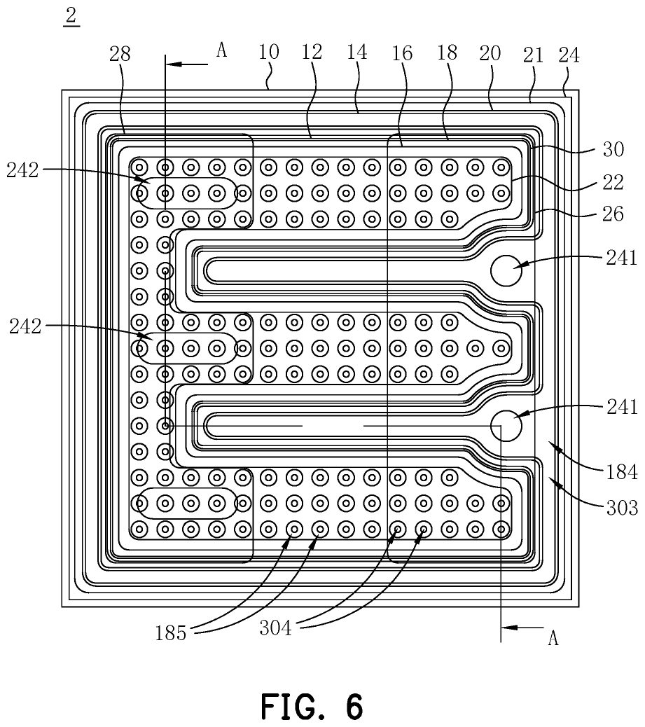

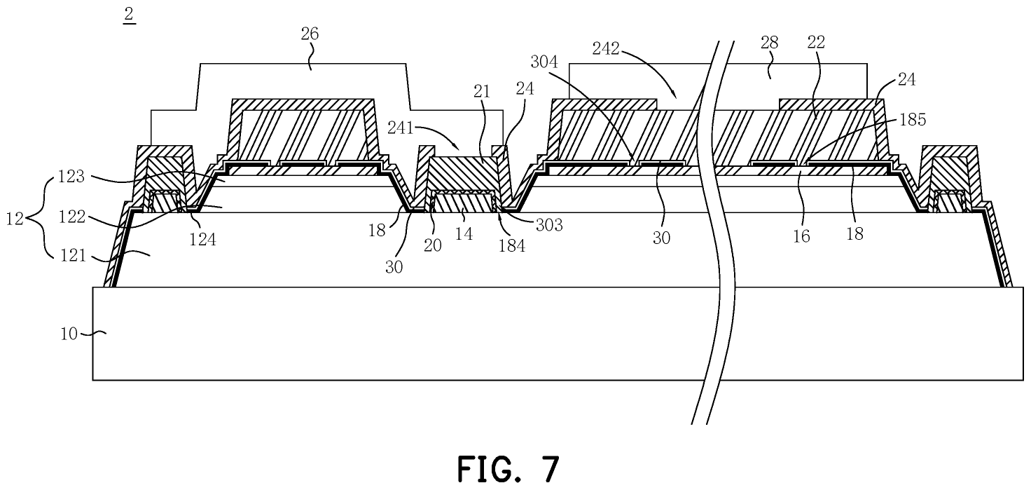

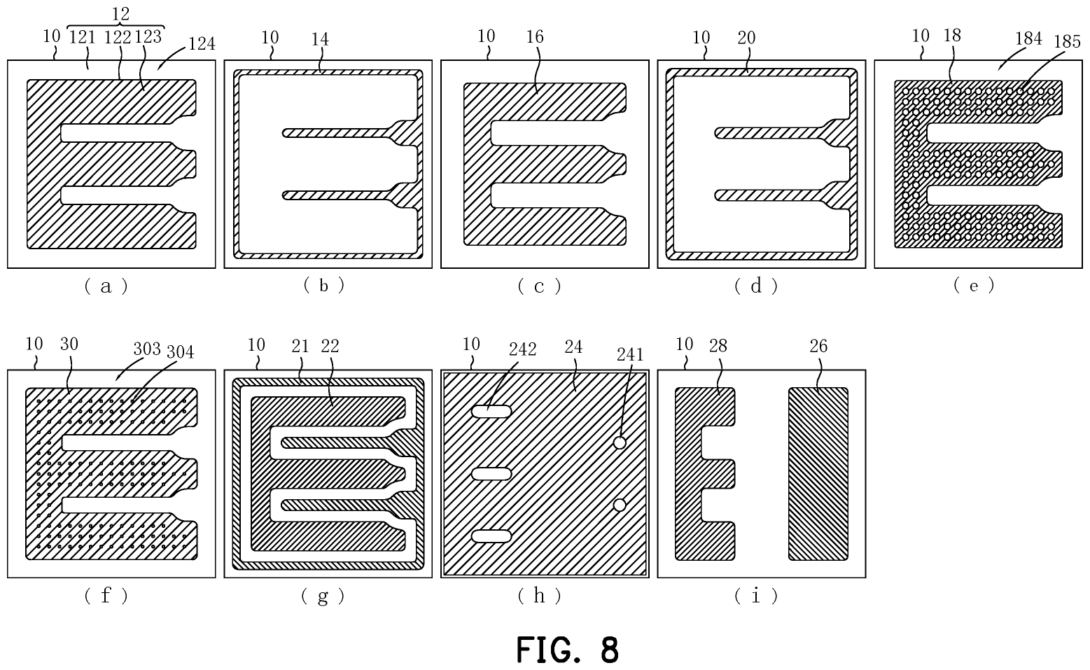

Referring to FIG. 6, FIG. 7 and FIG. 8, FIG. 6 is a schematic top view of the structure of an ultraviolet light emitting diode (UV LED) 2 according to a second embodiment of the disclosure, FIG. 7 is a schematic longitudinal cross-sectional view taken along section line A-A of FIG. 6, and FIG. 8 is a schematic top view of every structure of the UV LED 2 shown in FIG. 6. To achieve at least one of the aforementioned advantages or other advantages, the second embodiment of the disclosure further provides the UV LED 2. Compared with the UV LED 1 shown in FIG. 1, the UV LED 2 of the embodiment further includes a first current blocking layer 30. The first current blocking layer 30 covers the insulating dimming structure 18 to further improve the insulating protection and anti-leakage performance. The first current blocking layer 30 has a third conductive hole 303 and a fourth conductive hole 304. When overseen from the top of the UV LED 2 toward the epitaxial structure 12, as shown in FIG. 6 and FIG. 8, the third conductive hole 303 is disposed in the first conductive hole 184 for exposing the first protecting electrode 20; and the fourth conductive hole 304 is disposed in the second conductive hole 185 for exposing the second contact electrode 16. The first current blocking layer 30 is formed on the insulating dimming structure 18 after the insulating dimming structure 18 is prepared; and next, after the first current blocking layer 30 is prepared, the first connecting electrode 21 and the second connecting electrode 22 are disposed on the first current blocking layer 30.

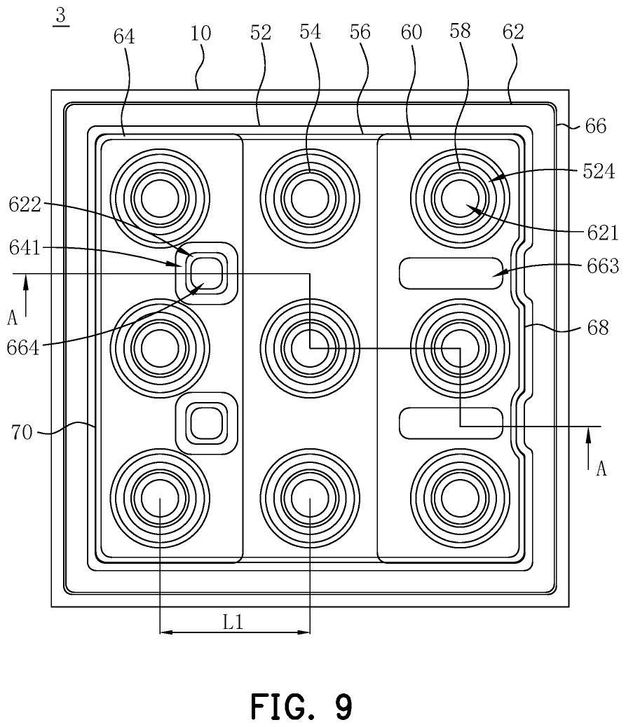

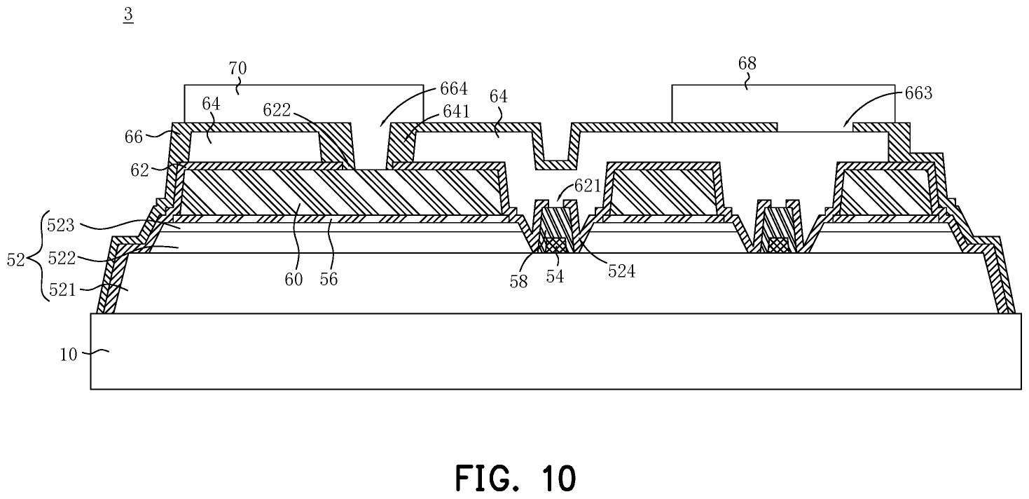

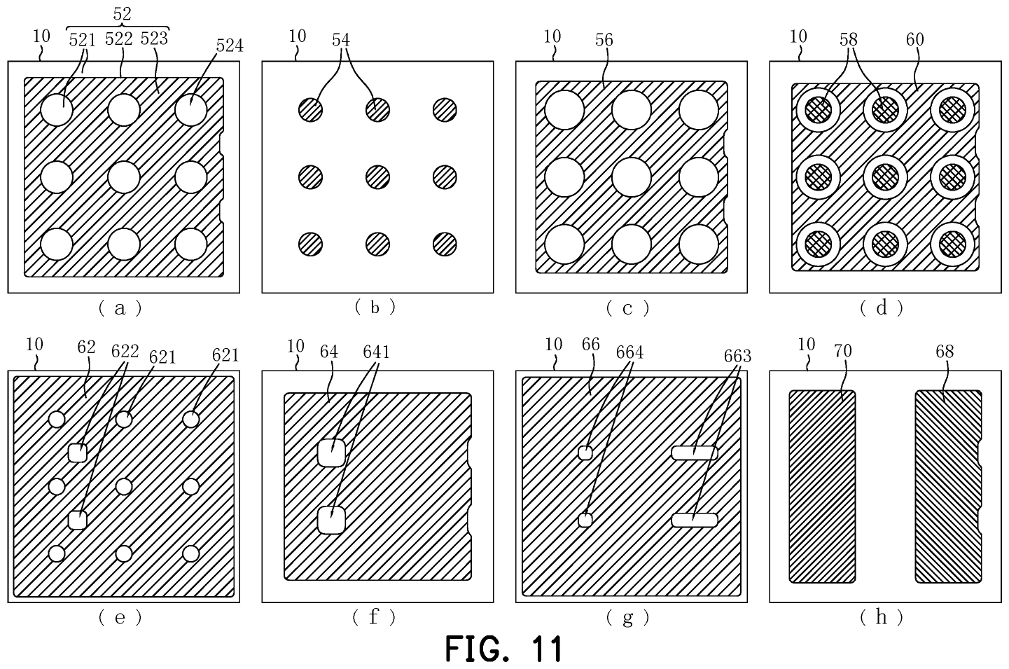

Referring to FIG. 9, FIG. 10 and FIG. 11, FIG. 9 is a schematic top view of the structure of an ultraviolet light emitting diode (UV LED) 3 according to a third embodiment of the disclosure, FIG. 10 is a schematic longitudinal cross-sectional view taken along section line A-A of FIG. 9, and FIG. 11 is a schematic top view of every structure of the UV LED 3 shown in FIG. 9, As shown in the drawings, the UV LED 3 may include at least an epitaxial structure 52, the first contact electrode 54, a second contact electrode 56, a first connecting electrode 58, a second connecting electrode 60, a first insulating structure 62, a third connecting electrode 64, a second insulating structure 66, a first pad 68, and a second pad 70.

The epitaxial structure 52 is disposed on the upper surface of the substrate 10. For the selection of layers and materials of the epitaxial structure 52, refer to the first embodiment. The epitaxial structure 52 includes a first semiconductor layer 521, a light emitting layer 522, and a second semiconductor layer 523 sequentially stacked along the stacking direction. The stacking direction refers to the direction in which components are stacked on the upper surface of the substrate 10, and the stacking direction in the embodiment is the direction from the substrate 10 to the pads (the first pad 68 and the second pad 70). In the illustrated embodiment, the first semiconductor layer 521 in the epitaxial structure 52 is formed on the substrate 10. The first semiconductor layer 521 can be an N-type semiconductor layer and can provide the light emitting layer 522 with electrons under the action of a power source. In the illustrated embodiment, the second semiconductor layer 523 in the epitaxial structure 52 is a P-type semiconductor layer, which can provide the light emitting layer 522 with holes under the action of a power supply.

Compared with the UV LED 1 shown in FIG. 1, the epitaxial structure 52 of the UV LED 3 in the embodiment has multiple conductive holes 524 (i.e., the mesa of the first semiconductor layer 521 is not completely communicating), and the multiple conductive holes 524 penetrate from the upper surface of the second semiconductor layer 523 down to the upper surface of the first semiconductor layer 521 to expose the first semiconductor layer 521. When overseen from the top of the UV LED 3 toward the epitaxial structure 52, as shown in FIG. 9, the conductive holes 524 are disposed inside the second semiconductor layer 523 at an interval of a first distance LI, so that the current distributively flows into the first semiconductor layer 521 below through the conductive holes 524 to achieve the effect of uniform current distribution. Specifically, in the epitaxial structure 12 of the UV LED 1 shown in FIG, 1, a large area of the second semiconductor layer 123 and a large area of the light emitting layer 122 are etched to form the communicating mesa 124, and the communicating mesa 124 is disposed outside the second semiconductor layer 123. In contrast, in the UV LED 3 of the embodiment, multiple conductive holes 524 are formed in the second semiconductor layer 523 at an interval of the first distance L1. Therefore, the current may be distributed more evenly, the effect of current spread is ensured, the light emission effect of the UV LED 3 is improved, and also a larger area of the light emitting layer 522 is retained to increase the light output of the light emitting layer 522. Preferably, in a plan view, the sum of the areas of the conductive holes 524 is less than or equal to 50% of the area of the epitaxial structure 52. The sum of the areas of the conductive holes 524 refers to the sum of the areas of the first semiconductor layer 521 exposed by the conductive holes 524. As shown in the drawings, the conductive hole 524 is circular, but its shape and quantity are not particularly limited. The conductive hole 524 may be optionally distributed in a form with uniform spacing or a form with non-uniform spacing according to actual requirements. When in a form with non-uniform spacing, the first distance L1 between two adjacent conductive holes 524 is different from the first distance L1 between two other adjacent conductive holes 524.

The first distance L1 refers to the distance between the centers of two adjacent conductive holes 524. Preferably, the first distance L1 ranges from 100 to 150 μm, that is, the distance between the centers of the two adjacent conductive holes 524 ranges from 100 to 150 μm. The size of each conductive hole 524 ranges from 40 to 60 μm. For example, if the conductive hole 524 in the embodiment is circular, its size is the diameter of the circular conductive hole.

The first contact electrode 54 and the second contact electrode 56 are both disposed on the epitaxial structure 52 and electrically connected to the first semiconductor layer 521 and the second semiconductor layer 523, respectively. Specifically, the first contact electrode 54 is disposed on the upper surface of the first semiconductor layer 521 through multiple conductive holes 524 to form a good ohmic contact with the first semiconductor layer 521; and the second contact electrode 56 is disposed on the upper surface of the second semiconductor layer 523 to form a good ohmic contact with the second semiconductor layer 523. The materials of the first contact electrode 54 and the second contact electrode 56 can be designed with reference to the embodiment shown in FIG. 1.

The first connecting electrode 58 is disposed on the first contact electrode 54 to protect the first contact electrode 54 thereunder and prevent the first contact electrode 54 from being corroded by etching solutions or gases in subsequent processes, such as wet etching and dry etching. The first connecting electrode 58 may also function as a support, a raise pad, a current spreader and the like. Preferably, the first connecting electrode 58 completely covers the first contact electrode 54 to prevent metal precipitation in the first contact electrode 54, for example, to prevent Al metal from precipitation. The material of the first connecting electrode 58 may be one or more selected from Cr, Pt, Au, Ni, Ti, and Al. Preferably, the metal surface layer of the first connecting electrode 58 in contact with the first insulating structure 62 is a Ti metal layer or a Cr metal layer, so that a stable attachment relationship is formed between the first connecting electrode 58 and the first insulating structure 62. In addition, the metal surface layer of the first connecting electrode 58 in contact with the first insulating structure 62 may also be a Ni metal layer, a Pt metal layer, or the like.

The second connecting electrode 60 is disposed on the second contact electrode 56, and the material of the second connecting electrode 60 may be one or more selected from Cr, Pt, Au, Ni, Ti, and Al, Preferably, the metal surface layer of the second connecting electrode 60 in contact with the first insulating structure 62 is a Ti metal layer or a Cr metal layer, so that a stable attachment relationship is formed between the second connecting electrode 60 and the first insulating structure 62. In addition, the metal surface layer of the second connecting electrode 60 in contact with the first insulating structure 62 may also be a Ni metal layer, a Pt metal layer, or the like.

The first insulating structure 62 covers the epitaxial structure 52, the first connecting electrode 58, and the second connecting electrode 60. The first insulating structure 62 has a first opening 621 and a second opening 622, and the first opening 621 is disposed on the first connecting electrode 58 for exposing the first connecting electrode 58. The second opening 622 is disposed on the second connecting electrode 60 for exposing the second connecting electrode 60. Preferably, the number of the first openings 621 is plural, and the number of the first openings 621 is the same as the number of the conductive holes 524. When overseen from the top of the UV LED 3 toward the epitaxial structure 52, the first opening 621 is disposed inside the conductive hole 524.

The third connecting electrode 64 is disposed on the first insulating structure 62 and electrically connected to the first connecting electrode 58 through the first opening 621. The third connecting electrode 64 has a fifth opening 641 for exposing part of the second connecting electrode 60, and the second opening 622 is disposed inside the fifth opening 641 so that the second pad 70 may be electrically connected to the second connecting electrode 60 through the fifth opening 641.

The second insulating structure 66 covers the third connecting electrode 64 and the first insulating structure 62. The second insulating structure 66 has a third opening 663 and a fourth opening 664. The third opening 663 is disposed on the third connecting electrode 64 for exposing the third connecting electrode 64; the fourth opening 664 is disposed inside the second opening 622, that is, the fourth opening 664 is smaller than the second opening 622 and smaller than the fifth opening 641, and the fourth opening 664 is configured for exposing the second connecting electrode 60 so that the second pad 70 may be electrically connected to the second connecting electrodes 60 through the fourth opening 664.

The first insulating structure 62 and the second insulating structure 66 have different functions according to the position involved. For example, the sidewall covering the epitaxial structure 52 is configured to prevent the electrical connection between the first semiconductor layer 521 and the second semiconductor layer 523 resulting from the leakage of the conductive material, thereby reducing the abnormal short circuit of the LTV LED 3, but the embodiments of the disclosure are not limited thereto. The materials of the first insulating structure 62 and the second insulating structure 66 include non-conductive materials, The non-conductive material is preferably an inorganic material or a dielectric material. The inorganic material may include silica gel. The dielectric material includes electrically insulating materials, such as aluminum oxide, silicon nitride, silicon oxide, titanium oxide, or magnesium fluoride. For example, the insulating layer may be silicon dioxide, silicon nitride, titanium oxide, tantalum oxide, niobium oxide, barium titanate, or a combination thereof. The combination thereof may be, for example, a Bragg reflector (DBR) formed by repeatedly stacking two materials to improve the selection effect of ultraviolet light and improve the light extraction performance of the UV LED 3. In addition, the first insulating structure 62 may also adopt a similar structural design as the insulating dimming structure 18 in FIG. 3 and FIG. 4, that is, the first insulating structure 62 includes double insulating layers (the first stacked insulating layer and the second stacked. insulating layer) and a reflector sandwiched between the first stacked insulating layer and the second stacked insulating layer to implement the function of the optical resonance cavity, so that the wave band of its resonance matches the wave band of light emitted by the light emitting layer 522, and the light output intensity of the UV LED 3 is further improved.

The first pad 68 is disposed on the second insulating structure 66 and connected to the third connecting electrode 64 through the third opening 663. The second pad 70 is disposed on the second insulating structure 66 and is connected to the second connecting electrode 60 through the fourth opening 664, The first pad 68 and the second pad 70 may be formed simultaneourly using the same material in the same process and thus may have the same layer configuration.

Specifically, the UV LED 3 of the embodiment is designed with multiple conductive holes 524, and with the configuration of the double insulating layers of the first insulating structure 62 and the second insulating structure 66, the configuration positions of the first pad 68 and the second pad 70 may be distinguished. Moreover, no special design is required for the shapes of the first pad 68 and the second pad 70, the distance between the first pad 68 and the second pad 70 may be ensured, and problems in subsequent installation and use can be prevented.

With the configuration of the double insulating layers of the first insulating structure 62 and the second insulating structure 66, the risk of short circuit caused by the rupture of the insulating structure may also be reduced, In addition, with the configuration of the first connecting electrode 58, the first contact electrode 54 thereunder can be protected. The first contact electrode 54 can be prevented from being corroded by the corrosive solution or gas in the subsequent processes, such as wet etching and dry etching, and the stability and reliability of the UV LED 3 may be improved.

As shown in FIG. 11, the manufacturing process of the UV LED 3 is illustrated as follows.

First, as shown in part (a) of FIG. 11, the epitaxial structure 52 including the first semiconductor layer 521, the light emitting layer 522, and the second semiconductor layer 523 is grown on the substrate 10. Next, the second semiconductor layer 523 is etched downward until the first semiconductor layer 521 is etched to form multiple conductive holes 524, and the first semiconductor layer 521 is exposed. In addition, the edge portion of the epitaxial structure 52 may be optionally removed to further expose the substrate 10 to facilitate subsequent processes, such as cutting.

Next, as shown in part (b) of FIG. 11, the first contact electrode 54 is formed on the first semiconductor layer 521, and the first contact electrode 54 is connected to the first semiconductor layer 521 through the conductive hole 524; as shown in part (c) of FIG. 11, the second contact electrode 56 is formed on the second semiconductor layer 523. Optionally, considering that in the conventional manufacturing process of the UV LED 3, the N-side electrode is usually annealed at a high temperature to form an alloy electrode, and then a subsequent process, such as wet etching or dry etching, is directly performed to process structures, such as the insulating layer and the like, the N-side electrode is accordingly easily damaged by etching and corrosion, which destroys the overall performance of the UV LED 3.

Therefore, the first contact electrode 54 may be formed first, and then the second contact electrode 56 may be formed.

Next, as shown in part (d) of FIG. 11, the first connecting electrode 58 and the second connecting electrode 60 are formed on the first contact electrode 54 and the second contact electrode 56, respectively. Preferably, the first connecting electrode 58 completely covers the first contact electrode 54. Then, as shown in part of FIG. 11, the first insulating structure 62 covering the first connecting electrode 58, the second connecting electrode 60, and the epitaxial structure 52 is formed.

Subsequently, as shown in part (f) of FIG. 11, the third connecting electrode 64 is formed on the first insulating structure 62. The third connecting electrode 64 is connected to the first connecting electrode 58 through the first opening 621 of the first insulating structure 62. Then, as shown in part (g) of FIG. 11, the second insulating structure 66 is formed on the third. connecting electrode 64 and the first insulating structure 62.

Finally, as shown in part (h) of FIG. 11, the first pad 68 and the second pad 70 are formed on the second insulating structure 66, the first pad 68 is connected to the third connecting electrode 64 through the third opening 663, and the second pad 70 is connected to the second connecting electrode 60 through the fourth opening 664.

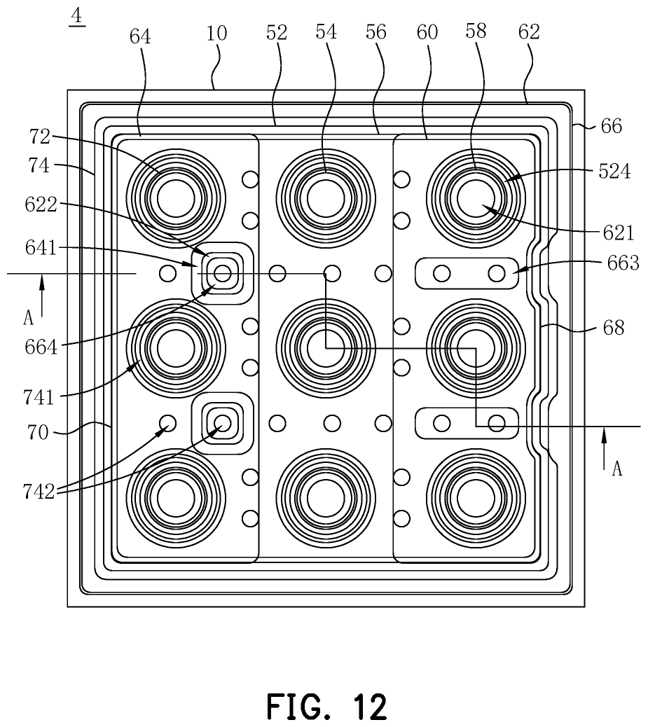

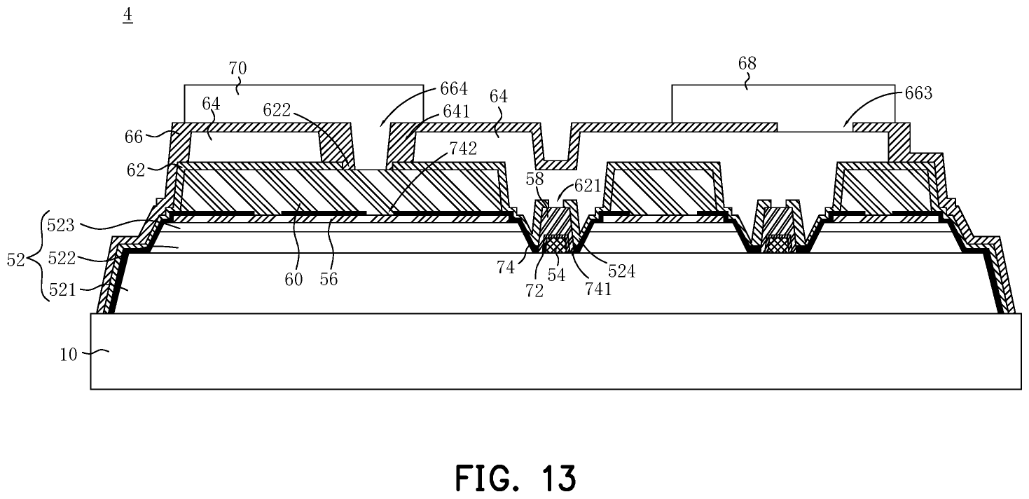

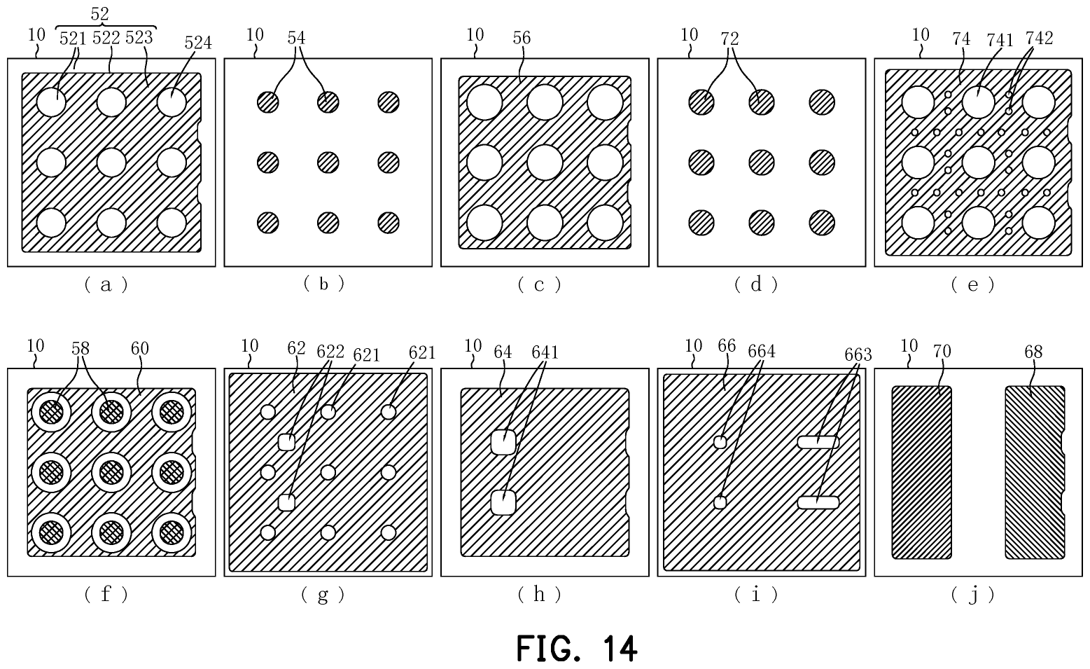

Referring to FIG. 12, FIG. 13, and FIG. 14, FIG. 12 is a schematic top view of the structure of a ultraviolet light emitting diode (UV LED) 4 according to the second embodiment of the disclosure, FIG. 13 is a schematic longitudinal cross-sectional view taken along section line A-A of FIG. 12, and FIG. 14 is a schematic top view of every structure of the UV LED 4 shown in FIG. 12. To achieve at least one of the aforementioned advantages or other advantages, the fourth embodiment of the disclosure further provides the UV LED 4. Compared with the UV LED 3 shown in FIG. 9, the UV LED 4 of the embodiment further includes a first protecting electrode 72 and an insulating dimming structure 74,

The first protecting electrode 72 is disposed between the first contact electrode 54 and the first connecting electrode 58 and completely covers the first contact electrode 54. The first protecting electrode 72 is formed on the first contact electrode 54 before the insulating dimming structure 74 to protect the first contact electrode 54 and prevent the first contact electrode 54 from being damaged by factors such as corrosion in the stage of forming the insulating dimming structure 74, and the stability and reliability of the UV LED 4 are improved. In one embodiment, the first protecting electrode 72 may be a single-layer structure, such as a Ti metal layer structure, and function to protect the first contact electrode 54; the first protecting electrode 72 may also be a metal structure of one or more selected from Cr, Pt, Au, Ni, Ti, and Al. On the basis of the protecting function, the height of the first electrode area may also be supplemented to reduce the height difference between the first electrode area and the second electrode area, thereby enhancing the bonding between the pad electrode and the packaged. substrate, and it also has the effect of spreading the current and improving the electrical properties.

The insulating dimming structure 74 covers the epitaxial structure 52, and the refractive index of the insulating dimming structure 74 is less than the refractive index of the second contact electrode 56, which may be configured to modulate the light with a specific wave band emitted by the light emitting layer 522, so that more light can be emitted, thereby improving the light extraction efficiency of the UV LED 4. By controlling the thickness of the insulating dimming structure 74, a suitable resonance cavity can be formed so that the wave band of the resonance matches the wave band of light emitted by the light emitting layer 522, thereby improving the light extraction efficiency of the UV LED 4. Specifically, the insulating dimming structure 74 covers part of the upper surface of the substrate 10, the sidewall and part of the upper surface of the first semiconductor layer 521, the sidewall of the light emitting layer 522, the sidewall and part of the upper surface of the second semiconductor layer 523, and the sidewall and part of the upper surface of the second contact electrode 56. The insulating dimming structure 74 has a first conductive hole 741 and a second conductive hole 742. The first conductive hole 741 is disposed on the first semiconductor layer 521 for exposing the first protecting electrode 72, so that the first connecting electrode 58 is electrically connected to the first protecting electrode 72 through the first conductive hole 741; the second conductive hole 742 is disposed on the second semiconductor layer 523 for exposing the second contact electrode 56, so that the second connecting electrode 60 is electrically connected to the second contact electrodes 56 through the second conductive holes 742. The first insulating structure 62 covers the insulating dimming structure 74. The second contact electrode 56 is made of a transparent conductive material, and the material of the insulating dimming structure 74 includes a dielectric material whose refractive index is less than the refractive index of the second contact electrode 56.

With the configuration of the insulating dimming structure 74, not only can the light emitting angle be improved, but also the reflection of ultraviolet light can be enhanced, and the light extraction efficiency of the UV LED 4 can be improved. The insulating dimming structure 74 can also function as an optical resonance cavity, so that the wave band of its resonance matches the wave band of light emitted by the light emitting layer 522 to further improve the light extraction performance of the UV LED 4. For the specific structure and modulated light of the insulating dimming structure 74, refer to the illustration of the insulating dimming structure 18 in the embodiments in FIG. 1 to FIG. 4. Both implementations of the insulating dimming structure 18 are adapted for the insulating dimming structure 74 of the embodiment. For example, the insulating dimming structure 74 of the embodiment may include a first insulating layer, a second insulating layer, and a reflecting layer sandwiched between the first insulating layer and the second insulating layer. Different thicknesses of the first insulating layer are different in modulating the light path, Preferably, when the refractive index of the dielectric material of the first insulating layer is less than the refractive index of the second contact electrode 56, the thickness of the first insulating layer is 1200-5000 Å. Such a thickness may form a favorable low-order resonance cavity, and the overall light output performance is favorable. The refractive index of the dielectric material of the first insulating layer is less than the refractive index of the second contact electrode. The reflectivity of the reflecting layer is greater than the reflectivity of the second contact electrode. The insulating dimming structure 74 may require no reflective properties but functions as an optical resonance cavity by virtue of the reflective properties of the second connecting electrode 60. Following this understanding, the rest may not be repeated herein.

An embodiment of the disclosure provides a light emitting device, which adopts the ultraviolet light emitting diodes 1, 3, or 4 illustrated in any of the foregoing embodiments. The light emitting device has favorable optoelectronic properties.

In summary, compared with the prior arts, the ultraviolet light emitting diodes 1, 2, 3, 4 and the light emitting device provided by the disclosure have favorable optoelectronic properties.

What is claimed is:

1. An ultraviolet light emitting diode, comprising:
an epitaxial structure, comprising a first semiconductor layer, a light emitting layer and a second semiconductor layer stacked in sequence;
a first contact electrode, disposed on the epitaxial structure and electrically connected to the first semiconductor layer;
a second contact electrode disposed on the epitaxial structure and electrically connected to the second semiconductor layer;
a first connecting electrode, disposed on the first contact electrode;
a first insulating structure, disposed on the first connecting electrode and the second contact electrode, wherein the first insulating structure covers the epitaxial structure, the first connecting electrode and the second contact electrode and has a first opening and a second opening, the first opening is disposed on the first connecting electrode, and the second opening is disposed on the second contact electrode,
wherein the first connecting electrode is disposed between the first opening and the first contact electrode.

2. The ultraviolet light emitting diode according to claim 1, wherein the ultraviolet light emitting diode further comprises a second connecting electrode, the second connecting electrode is disposed on the second contact electrode, the first insulating structure covers the second connecting electrode, and the second opening is disposed on the second connecting electrode.

3. The ultraviolet light emitting diode according to claim 2, wherein the ultraviolet light emitting diode further comprises a third connecting electrode, a second insulating structure, a first pad, and a second pad; the third connecting electrode is disposed on the first insulating structure and electrically connected to the first connecting electrode through the first opening; the third connecting electrode has a fifth opening; the fifth opening is configured for exposing part of the second connecting electrode; the second insulating structure covers the third connecting electrode and the first insulating structure; the second insulating structure has a third opening and a fourth opening; the third opening is disposed on the third connecting electrode; the fourth opening is disposed inside the fifth opening; the first pad is disposed on the second insulating structure and connected to the third connecting electrode through the third opening; and the second pad is disposed on the second insulating structure and connected to the second connecting electrode through the fourth opening.

4. The ultraviolet light emitting diode according to claim 2, wherein a metal surface layer of the first connecting electrode in contact with the first insulating structure is a first Ti metal layer or a first Cr metal layer, and a metal surface layer of the second connecting electrode in contact with the first insulating structure is a second Ti metal layer or a second Cr metal layer.

5. The ultraviolet light emitting diode according to claim 2, wherein the first insulating structure comprises a first stacked insulating layer, a second stacked insulating layer and a reflector sandwiched between the first stacked insulating layer and the second stacked insulating layer.

6. The ultraviolet light emitting diode according to claim 1, wherein the ultraviolet light emitting diode further comprises an insulating dimming structure disposed on the epitaxial structure and covering the second contact electrode, wherein a refractive index of the insulating dimming structure is less than a refractive index of the second contact electrode for modulating light emitted by the light emitting layer.

7. The ultraviolet light emitting diode according to claim 6, wherein the insulating dimming structure comprises a first insulating layer, a reflecting layer and a second insulating layer, wherein the first insulating layer is disposed on the second contact electrode, and the reflecting layer is disposed between the first insulating layer and the second insulating layer.

8. The ultraviolet light emitting diode according to claim 7, wherein a refractive index of a dielectric material of the first insulating layer is less than the refractive index of the second contact electrode.

9. The ultraviolet light emitting diode according to claim 7, wherein a thickness of the first insulating layer ranges from 1200 to 5000 Å.

10. The ultraviolet light emitting diode according to claim 7, wherein a reflectivity of the reflecting layer is greater than a reflectivity of the second contact electrode.

11. The ultraviolet light emitting diode according to claim 6, wherein the second contact electrode is made of a transparent conductive material, and a material of the insulating dimming structure comprises a dielectric material with a refractive index less than the refractive index of the second contact electrode.

12. The ultraviolet light emitting diode according to claim 11, wherein light transmittance of the second contact electrode is greater than 40%.

13. The ultraviolet light emitting diode according to claim 6, wherein the ultraviolet light emitting diode further comprises a first protecting electrode, and the first protecting electrode is disposed between the first contact electrode and the first connecting electrode and covers the first contact electrode.

14. The ultraviolet light emitting diode according to claim 13, wherein the first protecting electrode is formed on the epitaxial structure before the insulating dimming structure.

15. The ultraviolet light emitting diode according to claim 1, wherein the first connecting electrode completely covers the first contact electrode, and an orthogonal projection of the first opening on the epitaxial structure is completely overlapped with an orthogonal projection of the first connecting electrode on the epitaxial structure.

16. The ultraviolet light emitting diode according to claim 2, wherein the second connecting electrode is disposed between the second contact electrode and the second opening.

17. The ultraviolet light emitting diode according to claim 2, wherein an orthogonal projection of the second connecting electrode on the epitaxial structure is completely overlapped with an orthogonal projection of the second contact electrode on the epitaxial structure, and an orthogonal projection of the second opening on the epitaxial structure is completely overlapped with an orthogonal projection of the second connecting electrode on the epitaxial structure.

18. The ultraviolet light emitting diode according to claim 1, wherein the epitaxial structure has a plurality of conductive holes, the plurality of conductive holes penetrate from the second semiconductor layer down to the first semiconductor layer, and a sum of areas of the plurality of conductive holes is less than or equal to 50% of an area of the epitaxial structure.

19. The ultraviolet light emitting diode according to claim 1, wherein the first contact electrode is a Ti/Al/Au alloy structure, a Ti/Al/Ni/Au alloy structure, a Cr/Al/Ti/Au alloy structure or a Ti/Al/Au/Pt alloy structure.

20. A light emitting device comprising the ultraviolet light emitting diode according tee claim 1.
